(19) United States
(12) Patent Application Publication
(10) Pub. No.: US 2025/0316947 A1
(43) Pub. Date: Oct. 9, 2025

(54) SYSTEM FOR PUMPING RAMAN AMPLIFICATION

(71) Applicant: II-VI Delaware, Inc., Wilmington, DE (US)

(72) Inventors: Nadhum K. Zayer, Wilmington, DE (US); Ian P. McClean, Wilmington, DE (US)

(21) Appl. No.: 18/625,725

(22) Filed: Apr. 3, 2024

(51) Int. Cl. H01S 3/094; H01S 3/067; H01S 3/0941; H01S 3/30; H01S 5/024

(52) U.S. Cl. CPC H01S 3/094003; H01S 3/06762; H01S 3/094096; H01S 3/0941; H01S 3/302; H01S 5/02415

(57) ABSTRACT

Embodiments of the present disclosure show an optical system, with a dual-ended laser apparatus, that comprises a laser light source coupled to a controllable current drive. The dual-ended laser apparatus outputs a first light beam and a second light beam generated by the laser light source. A wavelength locker is coupled to one of the light beams, and controls the output wavelength via optical feedback signal. The system may be used to pump a fiber Raman amplifier.

### TECHNICAL FIELD

The present disclosure generally relates to a system for pumping Raman amplification.

### BACKGROUND

Aspects of the present disclosure relate to a system for pumping Raman amplification. Various issues may exist with conventional solutions for a system for pumping Raman amplification. In this regard, conventional systems and methods for a system for pumping Raman amplification may be costly, cumbersome, and/or inefficient.

Limitations and disadvantages of conventional systems and methods will become apparent to one of skill in the art, through comparison of such approaches with some aspects of the present methods and systems set forth in the remainder of this disclosure with reference to the drawings.

### BRIEF SUMMARY OF THE DISCLOSURE

Shown in and/or described in connection with at least one of the figures, and set forth more completely in the claims are waveguides and methods of forming such waveguides.

These and other advantages, aspects and novel features of the present disclosure, as well as details of illustrated embodiments thereof, will be more fully understood from the following description and drawings.

### BRIEF DESCRIPTION OF THE DRAWINGS

The various features and advantages of the present disclosure may be more readily understood with reference to the following detailed description taken in conjunction with the accompanying drawings, wherein like reference numerals designate like structural elements.

FIG. 1 is a block diagram illustrating an optical system, according to some embodiments of the present disclosure.

FIG. 2 is a block diagram illustrating further exemplary details of an optical system, according to some embodiments of the present disclosure.

### DESCRIPTION

The following discussion provides various examples of a system for pumping Raman amplification. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and/or “including,” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements.

Embodiments of the present disclosure may comprise an optical system, the system comprising a dual-ended laser apparatus, comprising a laser light source coupled to a controllable current drive. In accordance with various embodiments, the dual-ended laser apparatus may be operable to output a first light beam and a second light beam generated by the laser light source.

Embodiments may also comprise a wavelength locker coupled to the first light beam or the second light beam, the wavelength locker generating an optical feedback signal coupled to laser light source. Embodiments may also comprise a depolarizer coupled to the first light beam and the second light beam. In accordance with various embodiments, the depolarizer may be operable to combine the first light beam and the second light beam into a depolarized output beam.

In accordance with various embodiments, the depolarized output beam may be coupled to a fiber Raman amplifier to provide a pump laser signal. In accordance with various embodiments, the fiber Raman amplifier may be a distributed Raman amplifier or a discrete Raman amplifier. In accordance with various embodiments, the fiber Raman amplifier may be operable as a wideband amplifier in the C-band, L-band, C++ band, and/or L++bands.

In accordance with various embodiments, the fiber Raman amplifier may be pumped by a plurality of optical systems. In accordance with various embodiments, the wavelength locker may comprise a Bragg grating. In accordance with various embodiments, the output wavelength may be 1423 nm or 1445 nm or 1466 nm or 1493 nm or in the range from 1420 nm to 1528 nm.

In accordance with various embodiments, the first light beam and the second light beam may have a same output wavelength and have a same output power.

In accordance with various embodiments, the depolarizer may combine and depolarize the first light beam and the second light beam by multiplexing the first light beam and the second light beam with a 45-degree angle splice into a beam combiner component. In accordance with various embodiments, the optical system may be comprised in a single chip.

In accordance with various embodiments, the laser light source may be coupled to a thermo-electric cooler element.

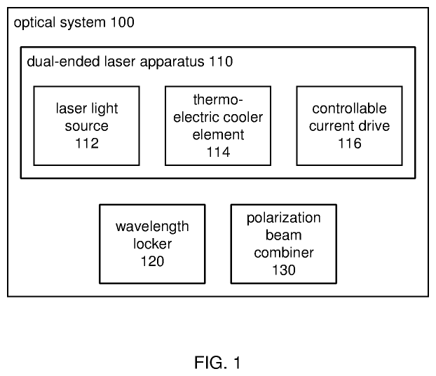

Referring now to FIG. 1, FIG. 1 is a block diagram that describes an optical system 100, according to some embodiments of the present disclosure. In some embodiments, the optical system 100 may include a dual-ended laser apparatus 110 and a depolarizer or polarization beam combiner (PBC) 130 coupled to a first light beam and a second light beam from the dual-ended laser apparatus 110. The optical system 100 may also include a wavelength locker 120 coupled to the first light beam or the second light beam, the wavelength locker 120 generating an optical feedback signal coupled to the laser light source. It is also possible to use a wavelength locker for each of the first light beam and the second light beam.

In some embodiments, the dual-ended laser apparatus 110 may include a laser light source 112 coupled to a thermo-electric cooler element (TEC) 114, and a controllable current drive 116. As will be understood by the skilled person, a dual-ended laser apparatus 110 may comprise only a TEC 114 or only a controllable current drive 116, or both. In accordance with various embodiments, a TEC 114 may not be necessary. The dual-ended laser apparatus 110 may be operable to output a first light beam and a second light beam generated by the laser light source 112. The feedback signal may be operable to control an output wavelength of the first light beam and the second light beam. The depolarizer or polarization beam combiner 130 may be operable to combine the first light beam and the second light beam into a depolarized output beam. In accordance with various embodiments of the invention, the PBC 130 may be any type of depolarizer, for example a lyot depolarizer or an integrated polarization beam combiner depolarizer (IPBCD).

In some embodiments, the depolarized output beam may be coupled to a fiber Raman amplifier to provide a pump laser signal. In some embodiments, the fiber Raman amplifier may be a distributed Raman amplifier or a discrete Raman amplifier. In some embodiments, the fiber Raman amplifier may be operable as a wideband amplifier in the C-band, L-band, C++ band, and/or L++bands. In some embodiments, the fiber Raman amplifier may be pumped by a plurality of the optical systems.

In some embodiments, the wavelength locker 120 may include a Bragg grating. In some embodiments, the output wavelength may be 1423 nm or 1445 nm or 1466 nm or 1493 nm or in the range from 1420 nm to 1528 nm. In some embodiments, the first light beam. The second light beam may include a same output power and a same output wavelength.

In some embodiments, the output first light beam may exit the dual-ended laser apparatus 110 in a spatial direction different from the output second light beam. In some embodiments, the depolarizer or polarization beam combiner 130 may combine and depolarize the first light beam and the second light beam by multiplexing the first light beam and the second light beam with a 45-degree angle splice into a beam combiner component. In some embodiments, the optical system 100 may be comprised in a single chip.

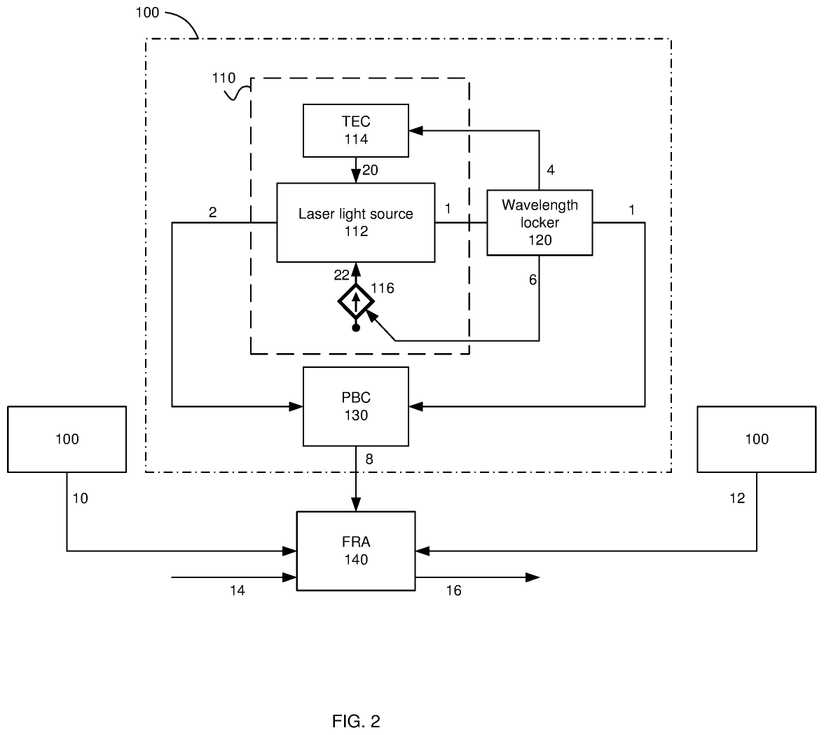

FIG. 2 is a block diagram illustrating further exemplary details of an optical system, according to some embodiments of the present disclosure. Like numerals used in FIG. 1 refer to like elements in FIG. 2. In addition, there is shown a plurality of optical systems 100 that may each be coupled to a fiber Raman amplifier (FRA) 140. There is also shown a first light beam 1 and a second light beam 2, a feedback signal 4, a feedback signal 6, and pump signals 8, 10, 12. There is shown a temperature control signal 20 and a current control signal 22. There is shown an input light 14 to the FRA 140, and an amplified output signal 16 from the FRA 140.

In some embodiments, a fiber Raman amplifier 140 may be used as a wideband amplifier for telecommunication applications, for example. In such applications, it may be desirable to amplify signals over a wide band of, e.g., 40 nm. To achieve a wide amplification band, it may be necessary to pump the fiber Raman amplifier 140 using pumps at multiple wavelengths. This may be achieved by using a plurality of optical systems 100. For example, a plurality of optical systems 100 may provide pump signals 8, 10, 12 at different pump wavelengths to a fiber Raman amplifier 140. This may enable the fiber Raman amplifier 140 to amplify an input light signal 14 and to generate an output light signal 16.

A fiber Raman amplifier 140 may be created by inserting a pump laser power into an optical fiber above a threshold for non-linear modification of the refractive index. This may result in stimulated energy transfer from the pump laser to an optical signal 14 traveling within the fiber. The stimulated process may generate an amplified output signal 16. Gain may be achieved when signal and pump polarizations may be closely matched, thus pump laser signals 8, 10, 12, are desired with a low degree of polarization. Generally, pump laser signals 8, 10, 12 may be most desirable in the band of 1400 to 1528 nm, for example. In some embodiments, it may be desirable to use two laser signals of the same wavelength each. For example, if four pump wavelengths may be desired, a conventional system may need eight laser diodes and associated control electronics. This may require high-power dissipation and may be costly to implement. In accordance with various embodiments of the present disclosure, the present disclosure may provide an advantageous solution by using laser light sources 112 that are operable to generate two light beams using one set of control elements, for example a TEC 114 and a controllable current source 116, and a wavelength locker 120.

A light source 112 generating two pump signals, a first light beam 1 and a second light beam 2, may be implemented in a single chip with a single TEC 114 and a single controllable current source 116, and one wavelength locker 120. In accordance with various embodiments, a TEC 114 may not be required. Thus, in accordance with various embodiments of the present disclosure, reduced electrical power dissipation, and reduced cost may be advantages of the present disclosure.

A laser light source 112 may generate a first light beam 1, and a second light beam 2. The first light beam 1 and the second light beam 2 may be at a same power and a same wavelength, when generated e.g., in a single semiconductor, for example a dual output VCSEL. In accordance with various embodiments, the laser light source 112 may be a ridge waveguide laser or any other type of edge emitting laser. The wavelength of the first light beam 1 and the second light beam 2 may be controlled together by using one or more wavelength locker 120. A wavelength locker 120 may be operable to stabilize and control the wavelength of the first light beam 1 and the second light beam 2 of the laser light source 112. This may be desirable in Raman amplifier applications, where locking the wavelength may allow for consistent gain over wide operating conditions. In these applications, maintaining a precise wavelength may be advantageous for ensuring that the optical gain may be consistent for any data transmission wavelength.

The wavelength locker 120 may control a wavelength of the first light beam 1 and the second light beam 2 of the laser light source 112 by optical feedback from a Bragg grating by setting up an optical cavity that may have a maximum gain at the desirable wavelength. This approach may be particularly desirable because it may not require active feedback but may be achieved by passive feedback. In accordance with various embodiments of the present disclosure, it may be sufficient and/or desirable to use a passive feedback at the first light beam 1 or the second light beam 2.

A wavelength locker 120 may use a fiber Bragg grating or volume Bragg grating. The wavelength locking may also be passive with optical feedback to the laser light source 112.

The TEC 114 may be a solid-state device that may use the Peltier effect, for example, to control the temperature of the laser light source 112. The temperature of the laser light source 112 may be critical to maintain desirable performance, including output power, output wavelength, and component aging.

Similarly, a controllable current source 116 may control an input current 22 to the laser light source 112, to control the laser light source 112 output wavelength of first light beam 1 and second light beam 2. Control may be carried out to both outputs at once or a separate control for each output with a suitable design of light source

The first light beam 1 and the second light beam 2 may be coupled to the polarization beam combiner 130 or any type of depolarizer.

A depolarizer may be an optical device designed to combine two incoming light beams with orthogonal polarization into a single output beam. This may be achieved using birefringent materials or dichroic filters, and/or splicing.

In accordance with some embodiments, it may be desirable to depolarize the light output from the optical system 100. This may be achieved in the PBC 130. The first light beam 1 and the second light beam 2 may be depolarized by multiplexing the two light beams with a 45° angle splice into a polarization beam combining component, or depolarizer. It may be advantageous for optimum polarization, that the two light beams have the same power. This may be easy to achieve using a single semiconductor light source 112 that generates two beams, for example a dual ended laser light source, for example a laser chip. Thus, the output beam 8 of the PBC 130 may generally be depolarized, which may be advantageous for a pump signal for a fiber Raman amplifier.

The present disclosure includes reference to certain examples, however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An optical system, said system comprising:
a dual-ended laser apparatus, comprising a laser light source coupled to a controllable current drive, wherein said dual-ended laser apparatus is operable to output a first light beam and a second light beam generated by said laser light source;
a wavelength locker coupled to said first light beam or said second light beam, said wavelength locker generating an optical feedback signal coupled to said laser light source; and
a depolarizer is coupled to said first light beam and said second light beam;
wherein said feedback signal is operable to control an output wavelength of said first light beam and said second light beam; and
wherein said depolarizer is operable to combine said first light beam and said second light beam into a depolarized output beam.

2. The system of claim 1, wherein said depolarized output beam is coupled to a fiber Raman amplifier to provide a pump laser signal.

3. The system of claim 2, wherein said fiber Raman amplifier is a distributed Raman amplifier or a discrete Raman amplifier

4. The system of claim 2, wherein said fiber Raman amplifier is operable as a wideband amplifier in the C-band, L-band, C++ band, and/or L++bands.

5. The system of claim 2, wherein said fiber Raman amplifier is pumped by a plurality of said optical systems.

6. The system of claim 1, wherein said wavelength locker comprises a fiber Bragg grating or a volume Bragg grating.

7. The system of claim 1, wherein said output wavelength is 1423 nm or 1445 nm or 1466 nm or 1493 nm or in the range from 1420 nm to 1528 nm

8. The system of claim 1, wherein said first light beam and said second light beam have a same said output wavelength and have a same output power.

9. The system of claim 1, wherein said output first light beam exits said dual-ended laser apparatus in a spatial direction different from said output second light beam.

10. The system of claim 1, wherein said depolarizer may combine and depolarize said first light beam and said second light beam by multiplexing said first light beam and said second light beam with a 45-degree angle splice into a beam combiner component.

11. The system of claim 1, wherein said optical system is comprised in a single chip.

12. The system of claim 1, wherein said laser light source is coupled to a thermo-electric cooler element.
